(19) United States
(12) Patent Application Publication
(10) Pub. No.: US 2026/0341649 A1
(43) Pub. Date: Oct. 29, 2026

(54) PLASMA PROCESSING APPARATUS

(71) Applicant: Tokyo Electron Limited, Tokyo (JP)

(72) Inventors: Takehisa SAITO, Miyagi (JP); Yuki KAWADA, Miyagi (JP); Jun TAKASU, Miyagi (JP)

(73) Assignee: Tokyo Electron Limited, Tokyo (JP)

(21) Appl. No.: 19/698,925

(22) Filed: Jun. 5, 2026

Related U.S. Application Data
(63) Continuation of application No. PCT/JP2024/043824, filed on Dec. 11, 2024.

(30) Foreign Application Priority Data
Dec. 18, 2023 (JP) 2023-213217

(51) Int. Cl. H01J 37/32; H01F 27/28; H10P 72/00

(52) U.S. Cl. CPC H01J 37/32669; H01F 27/28; H01J 37/3211; H01J 37/3244; H01J 37/32834; H01J 2237/3343; H10P 72/0421

(57) ABSTRACT

A plasma processing apparatus includes a plasma processing chamber in which a plasma processing space is formed, a substrate support provided in the plasma processing chamber, a gas introducer having a gas introducing opening introducing a gas into the plasma processing space, an antenna provided above the plasma processing chamber and supplied with a source RF signal for forming plasma, an AC power supply for supplying the source RF signal to the antenna, an electromagnet provided radially outside the antenna and having an annular coil disposed concentrically with a central axis of the substrate support, a DC power supply for supplying power to the coil of the electromagnet, and controller circuitry that controls the DC power supply to the coil of the electromagnet such that a product of a number of turns of the coil and the current is within a range of 356 ampere-turns to 600 ampere-turns.

### CROSS-REFERENCE TO RELATED APPLICATIONS

This application is a continuation application of International Application No. PCT/JP2024/043824 filed on Dec. 11, 2024, and designated the U.S., which is based upon and claims priority to Japanese Patent Application No. 2023-213217 filed on Dec. 18, 2023, the entire contents of which are incorporated herein by reference.

### BACKGROUND

### 1. Technical Field

The present disclosure relates to a plasma processing apparatus.

### 2. Description of Related Art

Japanese Unexamined Patent Application Publication No. 2018-98094 (hereinafter “Patent Document 1”) discloses a plasma processing apparatus including a processing container, a placing table provided in the processing container and configured to place a workpiece thereon, a dielectric member having a facing surface that faces the placing table, a planar antenna provided on a surface of the dielectric member opposite to the facing surface and configured to introduce an induced electric field for plasma excitation into the processing container via the dielectric member, and an electromagnet group disposed along the outer circumference of the processing container and configured to form a magnetic field for moving ions in plasma based on the induced electric field along the facing surface of the dielectric member in the processing container.

### SUMMARY

According to one aspect of the present disclosure, there is provided a plasma processing apparatus that includes a plasma processing chamber in which a plasma processing space is formed, a substrate support provided in the plasma processing chamber, a gas introducer having a gas introducing opening introducing a gas into the plasma processing space, an antenna provided above the plasma processing chamber and supplied with a source RF signal for forming plasma, an AC power supply for supplying the source RF signal to the antenna, an electromagnet provided radially outside the antenna and having an annular coil disposed concentrically with a central axis of the substrate support, a DC power supply configured to supply power to the coil of the electromagnet, and controller circuitry configured to control a current supplied by the DC power supply to the coil of the electromagnet such that a product of a number of turns of the coil of the electromagnet and the current is within a range of 356 ampere-turns to 600 ampere-turns.

### BRIEF DESCRIPTION OF THE DRAWINGS

FIG. 1 is an example of a diagram for explaining an example configuration of an inductively coupled plasma processing apparatus;

FIG. 2 is an example of a partially enlarged view of a plasma processing apparatus;

FIG. 3 is a graph illustrating an example of the number of combinations of a frequency of a source RF signal and an adjustment range of a matching device that facilitate ignition and maintenance;

FIG. 4 is a graph illustrating an example of the number of combinations of a frequency of a source RF signal and an adjustment range of a matching device that facilitate ignition;

FIG. 5 is an example of a graph illustrating the relationship between the number of ampere-turns and a magnetic flux density of a coil of an electromagnet;

FIG. 6 is an example of a graph illustrating the relationship between a wire diameter and electrical characteristics of a coil;

FIG. 7 is an example of a prototype coil of an electromagnet; and

FIG. 8 is an example of a diagram illustrating the relationship between the magnetic field strength and the current value in each coil.

### DETAILED DESCRIPTION

In one aspect, the present disclosure provides a plasma processing apparatus that enables stable ignition and sustained maintenance of plasma.

Hereinafter, various exemplary embodiments will be described in detail with reference to the drawings. In each of the drawings, the same reference numerals denote the same or corresponding parts.

### Plasma Processing System

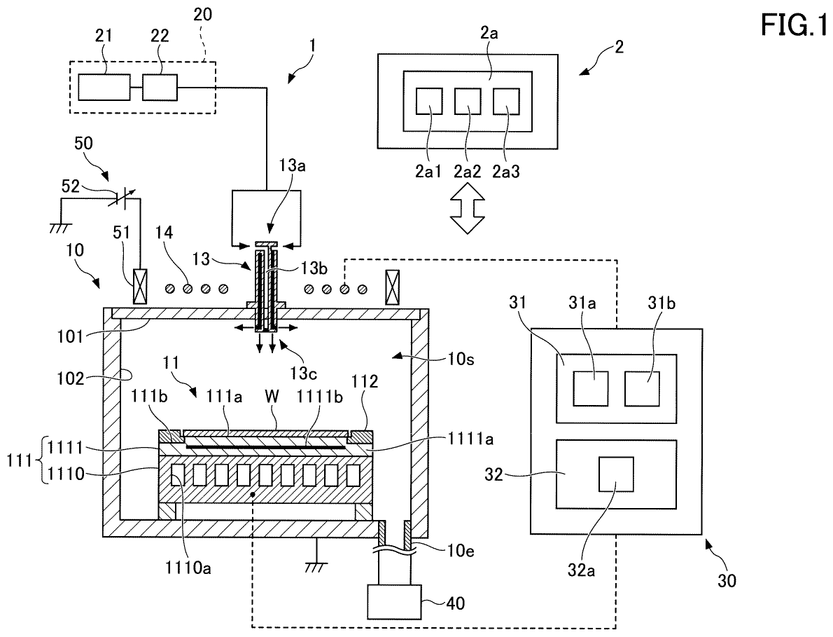

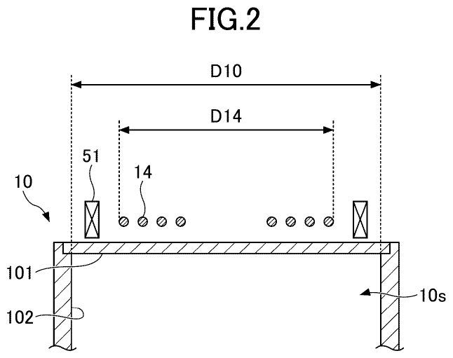

Hereinafter, a configuration example of a plasma processing system will be described with reference to FIGS. 1 and 2. FIG. 1 is an example of a diagram for explaining a configuration example of an inductively coupled plasma processing apparatus 1. FIG. 2 is an example of a partially enlarged view of the plasma processing apparatus 1. In FIG. 2, the structure of the upper portion of a plasma processing chamber 10 is illustrated, with a center gas injector 13 omitted.

The plasma processing system includes an inductively coupled plasma processing apparatus 1 and a controller 2. The inductively coupled plasma processing apparatus 1 includes the plasma processing chamber 10, a gas supply 20, a power supply 30, and an exhaust system 40. The plasma processing chamber 10 includes a dielectric window. The plasma processing apparatus 1 further includes a substrate support 11, a gas introducer, and an antenna 14. The substrate support 11 is disposed within the plasma processing chamber 10. The antenna 14 is disposed on or above the plasma processing chamber 10 (i.e., on or above a dielectric window 101). The plasma processing chamber 10 has a plasma processing space 10s defined by the dielectric window 101, side walls 102 of the plasma processing chamber 10, and the substrate support 11. The plasma processing chamber 10 has at least one gas supply port for supplying at least one processing gas to a plasma processing space 10s and at least one gas discharge port for discharging gas from the plasma processing space 10s. The plasma processing chamber 10 is grounded.

The substrate support 11 includes a main body 111 and a ring assembly 112. The main body 111 has a central region 111a for supporting the substrate W and an annular region 111b for supporting the ring assembly 112. A wafer is an example of a substrate W. The annular region 111b of the main body 111 surrounds the central region 111a of the main body 111 in a plan view. The substrate W is disposed on the central region 111a of the main body 111, and the ring assembly 112 is disposed on the annular region 111b of the main body 111 so as to surround the substrate W disposed on the central region 111a of the main body 111. Thus, the central region 111a is also referred to as a “substrate support surface” for supporting the substrate W, and the annular region 111b is also referred to as a “ring support surface” for supporting the ring assembly 112.

In one embodiment, the main body 111 includes a base 1110 and an electrostatic chuck 1111. The base 1110 includes a conductive member. The conductive member of the base 1110 may function as a bias electrode. The electrostatic chuck 1111 is disposed on the base 1110. The electrostatic chuck 1111 includes a ceramic member 1111a and an electrostatic electrode 1111b disposed within the ceramic member 1111a. The ceramic member 1111a has the central region 111a. In one embodiment, the ceramic member 1111a also has the annular region 111b. Other members surrounding the electrostatic chuck 1111, such as an annular electrostatic chuck or an annular insulating member, may have the annular region 111b. In this case, the ring assembly 112 may be disposed on the annular electrostatic chuck or the annular insulating member, or on both the electrostatic chuck 1111 and the annular insulating member. At least one RF/DC electrode coupled to an RF (radio frequency) power supply 31 or a DC (direct current) power supply 32, which are described below, or coupled to both of these supplies, may be disposed within the ceramic member 1111a. In this case, this RF/DC electrode functions as a bias electrode. The conductive member of the base 1110 and this RF/DC electrode may function as a plurality of bias electrodes. The electrostatic electrode 1111b may function as a bias electrode. Accordingly, the substrate support 11 includes at least one bias electrode.

The ring assembly 112 includes one or more annular members. In one embodiment, the one or more annular members include one or more edge rings and at least one cover ring. The edge rings are formed of a conductive or insulating material and the cover ring is formed of an insulating material.

The substrate support 11 may further include a temperature control module configured to regulate at least one of the electrostatic chuck 1111, the ring assembly 112, or the substrate to a target temperature. The temperature control module may include a heater, a heat transfer medium, a flow channel 1110a, or a combination thereof. A heat transfer fluid, such as brine or gas, flows through the flow channel 1110a. In one embodiment, the flow channel 1110a is formed in the base 1110 and the heater or heaters are disposed within the ceramic member 1111a of the electrostatic chuck 1111. The substrate support 11 may further include a heat transfer gas supply configured to supply a heat transfer gas to a gap between the rear surface of the substrate W and the central region 111a.

The gas introducer is configured to introduce at least one process gas from the gas supply 20 into the plasma processing space 10s. In one embodiment, the gas introducer includes a center gas injector (CGI) 13. The center gas injector 13 is disposed above the substrate support 11 and is attached to a central opening formed in the dielectric window 101. The center gas injector 13 has at least one gas supply opening 13a, at least one gas flow path 13b, and at least one gas introducing opening 13c. The process gas supplied to the gas supply opening 13a passes through the gas flow path 13b and is introduced into the plasma processing space 10s through the gas introducing opening 13c. In addition to or instead of the center gas injector 13, the gas introducer may include one or more side gas injectors (SGIs) attached to one or more openings formed in the sidewall 102.

The gas supply 20 may include at least one gas source 21 and at least one flow controller 22. In one embodiment, the gas supply 20 is configured to supply at least one process gas from a corresponding gas source 21 to the gas introducer via a corresponding flow controller 22. Each flow controller 22 may include, for example, a mass flow controller or a pressure controlled flow controller. Furthermore, the gas supply 20 may include one or more flow modulation devices that modulate or pulse the flow rate of the at least one process gas.

The power supply 30 includes the RF power supply 31 coupled to the plasma processing chamber 10 via at least one impedance matching circuit. The RF power supply 31 can be an AC power supply and can be configured to supply at least one RF signal (RF power) to at least one bias electrode and the antenna 14. Plasma is thereby formed from the at least one process gas supplied to the plasma processing space 10s. Accordingly, the RF power supply 31 may function as at least part of a plasma generator configured to form plasma from one or more process gases in plasma processing chamber 10. By supplying a bias RF signal to at least one bias electrode, a bias potential can be generated in substrate W to draw ions in the formed plasma to the substrate W.

In one embodiment, the RF power supply 31 includes a first RF generator 31a and a second RF generator 31b. The first RF generator 31a is coupled to the antenna 14 and is configured to generate a source RF signal (source RF power) for forming plasma via at least one impedance matching circuit. In one embodiment, the source RF signal has a frequency within the range of 10 MHz to 150 MHz. In one embodiment, the first RF generator 31a may be configured to generate a plurality of source RF signals having different frequencies. The generated one or more source RF signals are supplied to the antenna 14.

The second RF generator 31b is coupled to at least one bias electrode via at least one impedance matching circuit and configured to generate a bias RF signal (bias RF power). The frequency of the bias RF signal may be the same as or different from the frequency of the source RF signal. In one embodiment, the bias RF signal has a frequency that is lower than the frequency of the source RF signal. In one embodiment, the bias RF signal has a frequency within the range of 100 kHz to 60 MHz. In one embodiment, the second RF generator 31b may be configured to generate a plurality of bias RF signals having different frequencies. The generated bias RF signal or signals are supplied to at least one bias electrode. In various embodiments, at least one of the source RF signal or the bias RF signal may be pulsed.

The power supply 30 may further include the DC power supply 32 coupled to the plasma processing chamber 10. The DC power supply 32 includes a bias DC generator 32a. In one embodiment, the bias DC generator 32a is coupled to at least one bias electrode and is configured to generate a bias DC signal. The generated bias DC signal is applied to the at least one bias electrode.

In various embodiments, the bias DC signal may be pulsed. In this case, a sequence of voltage pulses is applied to the at least one bias electrode. The voltage pulses may have pulse waveforms that are rectangular, trapezoidal, triangular, or combinations of these shapes. In one embodiment, a waveform generator for generating a sequence of voltage pulses from the DC signal is connected between the bias DC generator 32a and the at least one bias electrode. Therefore, the bias DC generator 32a and the waveform generator constitute a voltage pulse generator. The voltage pulses may have positive polarity or negative polarity. The sequence of voltage pulses may include one or more positive polarity voltage pulses and one or more negative polarity voltage pulses within a single period. The bias DC generator 32a may be provided in addition to the RF power supply 31 or may be provided in place of the second RF generator 31b.

The antenna 14 includes one or more coils. In one embodiment, antenna 14 may include a coaxially disposed outer coil and an inner coil. In this case, the RF power supply 31 may be connected to both the outer coil and the inner coil, or to either the outer coil or the inner coil. In the former case, the same RF generator may be connected to both the outer coil and the inner coil, or separate RF generators may be connected to the outer coil and the inner coil separately.

The exhaust system 40 may be connected, for example, to a gas exhaust opening 10e provided at the bottom of the plasma processing chamber 10. The exhaust system 40 may include a pressure regulating valve and a vacuum pump. The pressure regulating valve regulates the pressure in the plasma processing space 10s. The vacuum pump may include a turbomolecular pump, a dry pump, or a combination of these pumps.

The plasma processing apparatus 1 has a magnetic field generator 50 for generating a magnetic field in the plasma processing space 10s. The magnetic field generator 50 has an electromagnet 51 and a power supply 52. The power supply 52 may be a DC power supply.

The electromagnet 51 has an annular coil disposed concentrically with the central axis (axis through the center of the substrate support surface and perpendicular to the substrate support surface) of the substrate support 11. Herein, as illustrated in FIG. 2, the electromagnet 51 is disposed above the plasma processing chamber 10 (dielectric window 101). The electromagnet 51 is disposed outside the diameter D14 of the antenna 14 in the radial direction.

The electromagnet 51 is disposed inside the diameter D10 of the inner wall of the plasma processing chamber 10 in the radial direction. The electromagnet 51 may be disposed outside the diameter D10 of the inner wall of the plasma processing chamber 10 in the radial direction.

Specifically, when the diameter D14 of the antenna 14 is within the range of 300 mm to 500 mm and the diameter D10 of the inner wall of the plasma processing chamber 10 is within the range of 540 mm to 580 mm, the inner diameter of the coil of the electromagnet 51 is preferably within the range of 540 mm to 640 mm.

The power supply 52 supplies power to the coil of the electromagnet 51. Thus, the electromagnet 51 generates a magnetic field in the plasma processing space 10s. The power supply 52 supplies a continuous wave or pulsed power to the coil of the electromagnet 51 to generate a continuous wave or pulsed magnetic field in the plasma processing space 10s.

The controller 2 processes computer-executable instructions that cause the plasma processing apparatus 1 to perform the various steps described herein. The controller 2 may be configured to control elements of the plasma processing apparatus 1 to perform the various steps described herein. In one embodiment, some or all of the controller 2 may be included in the plasma processing apparatus 1. The controller 2 may include a processor 2a1, a storage 2a2, and a communication interface 2a3. The controller 2 may be implemented by a computer 2a, for example. The processor 2a1 may be configured to perform various control operations by reading a program from the storage 2a2 and executing the read program. This program may be stored in advance in the storage 2a2 or may be acquired via a medium when necessary. The acquired program is stored in the storage 2a2, read from the storage 2a2 by the processor 2a1, and executed. The medium may be any storage medium readable by the computer 2a or a communication line connected to the communication interface 2a3. The processor 2a1 may be a CPU (central processing unit). The storage 2a2 may include RAM (random access memory), ROM (read only memory), HDD (hard disk drive), SSD (solid state drive), or a combination of these components. The communication interface 2a3 may communicate with the plasma processing apparatus 1 via a communication line such as a LAN (local area network). The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium, such as a CD-ROM or DVD, and/or the memory of a FPGA or ASIC.

Next, a method of forming plasma in the plasma processing space 10s using the plasma processing apparatus 1 will be described.

With the miniaturization of semiconductor devices formed on the substrate W, improvement in plasma uniformity is desirable. In a plasma etching process, plasma formed in the plasma processing chamber 10 under a low pressure (1 mTorr to 20 mTorr) is highly uniform, and as a result, the uniformity of the etching rate is improved.

On the other hand, under low-pressure conditions, the density of gas molecules is low and collisions between gas molecules are reduced, making it difficult to ignite and maintain the plasma. Furthermore, with the miniaturization of semiconductor devices formed on the substrate W, there is a limit to increasing the power of a source RF signal (source RF power) for forming plasma.

When a magnetic field is applied by the magnetic field generator 50, charged particles in the plasma move along magnetic field lines. As a result, the distance traveled by the charged particles before reaching the sheath is increased. In other words, the probability that the charged particles collide with other gas molecules or the like before reaching the sheath is increased, thereby increasing the plasma density. Accordingly, deactivation of the plasma can be suppressed even under low-pressure conditions.

To form plasma, it is preferable that the controller 2 first control the power supply 52 to supply power to the coil of the electromagnet 51 and then control the first RF generator 31a to supply a source RF signal to the antenna 14. In this manner, the plasma can be easily ignited.

In the plasma processing space 10s, a dynamic magnetic flux generated by supplying the source RF signal to the antenna 14 and a static magnetic flux generated by the magnetic field generator 50 are formed. Herein, if the strength of the static magnetic field generated by the magnetic field generator 50 is excessively increased, the formation of inductively coupled plasma (ICP) caused by supplying the source RF signal to the antenna 14 may be inhibited. Therefore, an appropriate static magnetic field strength and static magnetic field distribution of the magnetic field generator 50 that do not deteriorate the formation efficiency of the inductively coupled plasma are desirable or may be selected.

Herein, the static magnetic field strength immediately below the dielectric window (top plate) 101 in the vicinity of the antenna 14, which forms a dynamic magnetic flux, will be described.

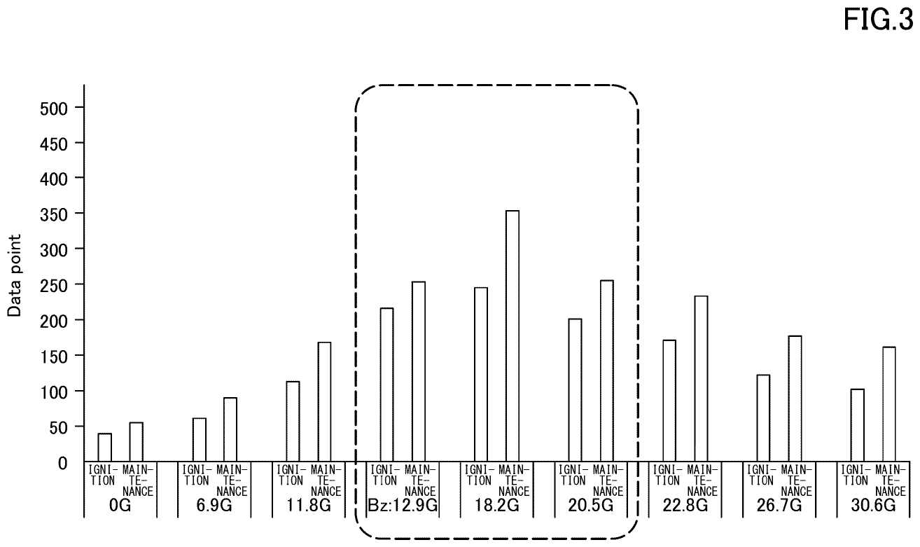

FIG. 3 is a graph illustrating an example of the number of combinations of a frequency of a source RF signal and an adjustment range of a matching device that facilitate ignition and maintenance.

Herein, for each static magnetic field strength (0 G to 30.6 G) at a pressure of 3 mTorr in the plasma processing chamber 10, the reflectance was measured for each combination (data point) of a frequency of a source RF signal applied to the antenna 14 at the time of plasma ignition and an adjustment range (variable capacitance) of a matching device provided in the power supply. Then, data points with a reflectance of 50% or less were counted.

Similarly, for each static magnetic field strength (0 G to 30.6 G), the reflectance was measured for each combination (data point) of a frequency of a source RF signal applied to the antenna 14 at the time of plasma maintenance and an adjustment range (variable capacitance) of the matching device provided in the power supply. Data points with a reflectance of 50% or less were counted.

As illustrated in FIG. 3, when the static magnetic field strength is within the range of 13 G to 22 G (in the example of FIG. 3, within the range of 12.9 G to 20.5 G indicated by the broken line), the number of data points in which the reflectance is 50% or less at the time of ignition and maintenance increases. In other words, the range of combinations of the frequency of the source RF signal applied to the antenna 14 and the adjustment range (variable capacitance) of the matching device that improves plasma ignitability and plasma maintainability is wide.

In other words, setting the strength of the static magnetic field generated by the magnetic field generator 50 within the range of 13 G to 22 G expands the range of selectable combinations of the frequency of the source RF signal applied to the antenna 14 and the adjustment range (variable capacitance) of the matching device that enable ignition and maintenance of inductively coupled plasma. Thus, plasma can be stably ignited and maintained under low-pressure conditions.

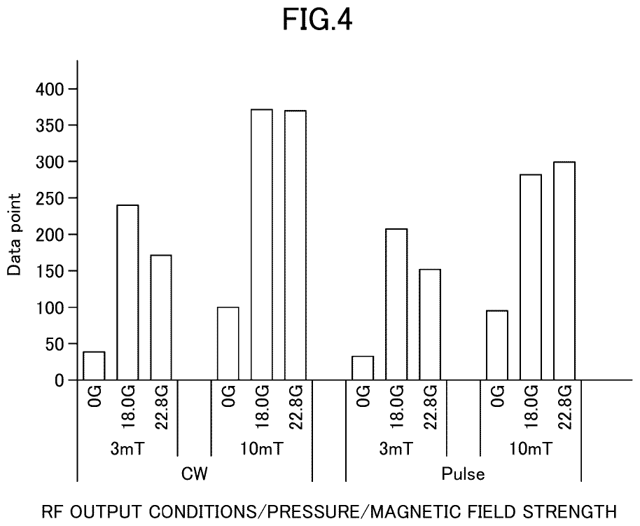

FIG. 4 is a graph illustrating an example of the number of combinations of the frequency of the source RF signal and the adjustment range of the matching device that enable easy ignition.

Herein, when the source RF signal supplied to the antenna 14 is a continuous wave (CW) or pulse, the reflectance was measured for each combination (data point) of the frequency of the source RF signal applied to the antenna 14 and the adjustment range (variable capacitance) of the matching device provided in the power supply at the time of plasma ignition for each combination of pressure (3 mTorr, 10 mTorr) and static magnetic field strength (0 G to 22.8 G) in the plasma processing chamber 10, respectively. Then, data points with reflectance of 50% or less were counted.

As illustrated in FIG. 4, by setting the strength of the static magnetic field generated by the magnetic field generator 50 within the range of 13 G to 22 G (18.0 G in the example of FIG. 4), when the pressure in the plasma processing chamber 10 is within the range of 3 mTorr to 10 mTorr, the range of selectable combinations of the frequency of the source RF signal applied to the antenna 14 and the adjustment range (variable capacitance) of the matching device that enable ignition and maintenance of inductively coupled plasma is expanded. Furthermore, even when the source RF signal supplied to the antenna 14 is either in a form of continuous wave (CW) or pulse, the range of the selectable combinations of the frequency of the source RF signal applied to the antenna 14 and the adjustment range (variable capacitance) of the matching device that enable ignition of inductively coupled plasma is expanded. Thus, the plasma can be stably ignited and maintained under low-pressure conditions.

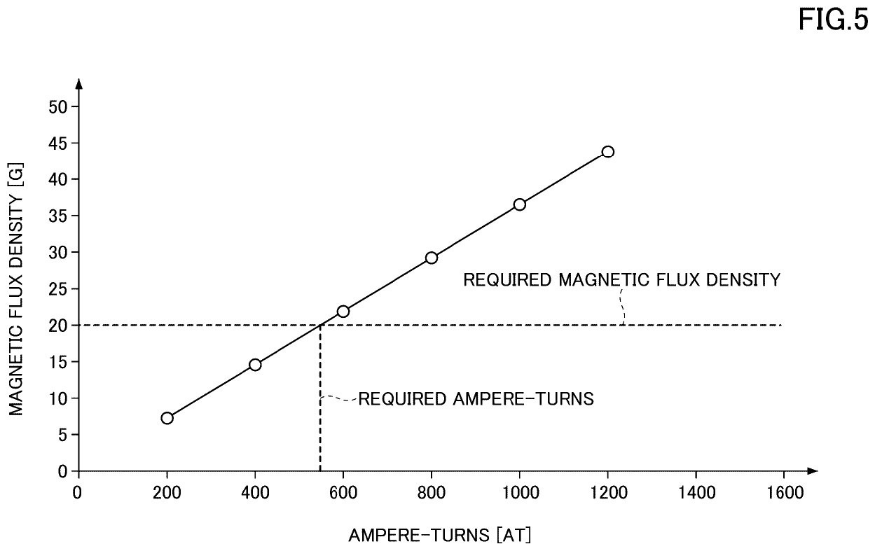

FIG. 5 is an example of a graph illustrating the relationship between the number of ampere-turns of the coil of the electromagnet 51 and the magnetic flux density. The number of ampere-turns (AT) on the horizontal axis is the product of the number of turns of the coil and the current (ampere) flowing through the coil. The vertical axis is the magnetic flux density (G).

As illustrated in FIG. 5, when the required magnetic flux density (20 G in the example of FIG. 5) is determined, the required number of ampere-turns is determined from the graph illustrated in FIG. 5.

Accordingly, when the strength of the static magnetic field generated by the electromagnet 51 falls within the range of 13 G to 22 G, the number of ampere-turns of the coil of the electromagnet 51 falls within the range of 356 AT to 600 AT. In other words, setting the number of ampere-turns of the coil of the electromagnet 51 within the range of 356 AT to 600 AT expands the range of selectable combinations of the frequency of the source RF signal applied to the antenna 14 and the adjustment range (variable capacitance) of the matching device that enable ignition and maintenance of inductively coupled plasma. As a result, the plasma can be stably ignited and maintained under low-pressure conditions.

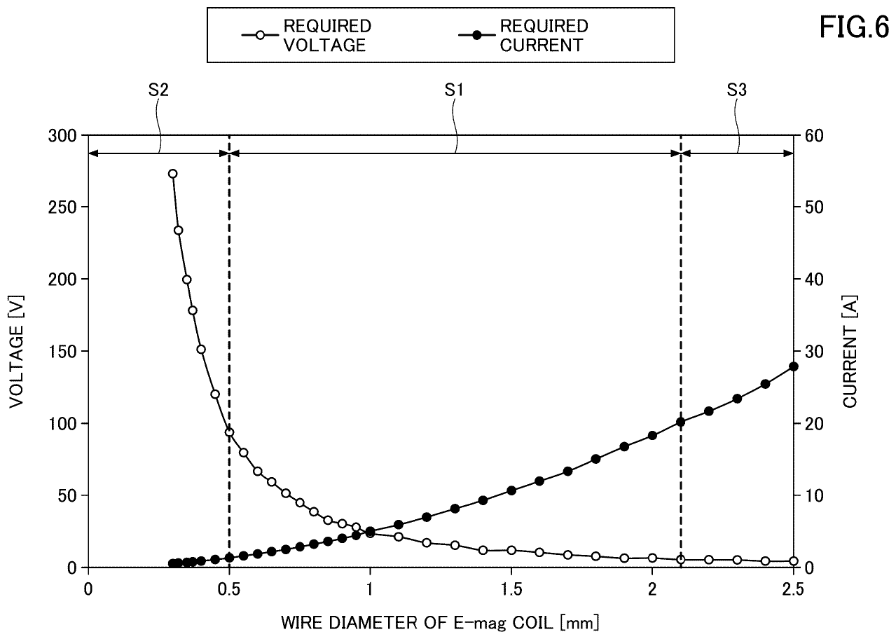

FIG. 6 is an example of a graph illustrating the relationship between the wire diameter of the coil and the electrical characteristics. Herein, the relationship between the wire diameter of the coil and the electrical characteristics in the case of 600 AT, which is the upper limit of the range of the number of ampere-turns, is illustrated as an example. The horizontal axis is the wire diameter of the coil of the electromagnet 51. The graph indicated by black dots represents the voltage applied to the coil when the number of ampere-turns is 600 AT (hereinafter, “required voltage”). The graph indicated by white dots represents the current flowing through the coil when the number of ampere-turns is 600 AT (hereinafter, “required current”).

Herein, in the region S2 where the coil diameter of the electromagnet 51 is less than 0.5 mm, the required voltage increases. In the region S3 where the coil diameter is larger than 2.1 mm, on the other hand, the required current increases. The coil diameter may be the wire diameter of the coil, as illustrated in FIG. 6. Therefore, the cost may increase due to the demand for the power supply 52 with a large output.

For this reason, the coil diameter of the electromagnet 51 is preferably within the range of 0.5 mm to 2.1 mm (region S1). According to FIG. 6, the required current is 1.3 A when the coil diameter of the electromagnet 51 is 0.5 mm, and the required current is 20 A when the coil diameter of the electromagnet 51 is 2.1 mm. Therefore, the current flowing through the coil is preferably within the range of 1.3 A to 20 A.

When the coil diameter of the electromagnet 51 is 2.1 mm and the static magnetic field strength is 13 G (corresponding to 356 AT), the current required for a 30-turn coil is 11.8 A. When the wire diameter of the coil of the electromagnet 51 is 0.5 mm and the static magnetic field strength is 22 G (corresponding to 600 AT), the current required for a 455-turn coil is 1.32 A. Therefore, the number of turns of the coil of the electromagnet 51 is preferably within the range of 30 to 455.

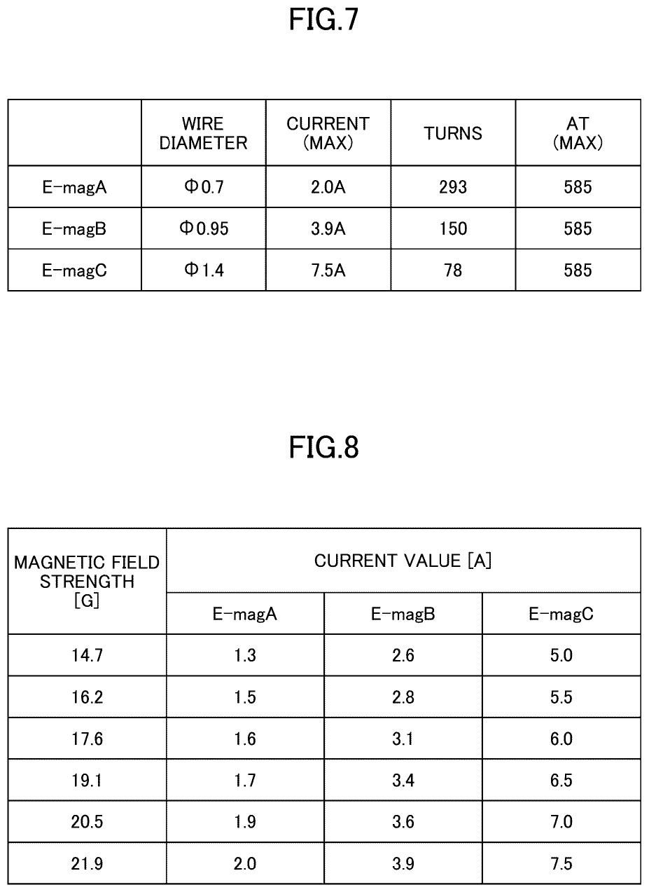

FIG. 7 is a diagram illustrating an example of prototype coils of the electromagnet 51. Herein, a first coil (E-magA), a second coil (E-magB), and a third coil (E-magC) were fabricated.

The first coil (E-magA) has a wire diameter of 0.7 mm. In this case, the maximum value of the current flowing through the coil is 2.0 A as illustrated in FIG. 6, when the number of ampere-turns is the maximum (600 AT). In the first coil (E-magA), the required current flowing through the 293-turn coil produced 585 ampere-turns, corresponding to a magnetic field strength of 21.9 G.

The second coil (E-magB) has a wire diameter of 0.95 mm. In this case, the maximum value of the current flowing through the coil is 3.9 A as illustrated in FIG. 6, when the number of ampere-turns is the maximum (600 AT). In the second coil (E-magB), the required current flowing through the 150-turn coil produced 585 ampere-turns, corresponding to a magnetic field strength of 21.9 G.

The third coil (E-magC) has a wire diameter of 1.4 mm. In this case, the maximum value of the current flowing through the coil is 7.5 A as illustrated in FIG. 6, when the number of ampere-turns is the maximum (600 AT). In the third coil (E-magC), the required current flowing through the 78-turn coil produced 585 ampere-turns, corresponding to a magnetic field strength of 21.9 G.

FIG. 8 is an example of a diagram illustrating the relationship between the magnetic field strength and the current value in each coil. Herein, for the first coil (E-magA), the second coil (E-magB), and the third coil (E-magC) fabricated experimentally, the current flowing through the coil was controlled so as to obtain a desired magnetic field strength.

As illustrated in FIG. 8, any of the first coil (E-magA), the second coil (E-magB), and the third coil (E-magC) can generate a desired magnetic field strength by controlling a current.

The embodiments disclosed above include, for example, the following aspects.

### Clause 1

A plasma processing apparatus including:
a plasma processing chamber in which plasma processing space is formed;
a substrate support provided in the plasma processing chamber;
a gas introducer configured to introduce a gas into the plasma processing space;
an antenna provided above the plasma processing chamber and supplied with a source RF signal for forming plasma;
an AC power supply for supplying the source RF signal to the antenna;
an electromagnet provided radially outside the antenna and having an annular coil disposed concentrically with a central axis of the substrate support;
a DC power supply configured to supply power to the coil of the electromagnet; and
a controller, wherein
the controller is configured to control the DC power supply within a range of ampere-turns to 600 ampere-turns, the ampere-turn being a product of a number of turns of the coil of the electromagnet and a current flowing through the coil of the electromagnet.

### Clause 2

The plasma processing apparatus according to Clause 1, wherein
a wire diameter of the coil of the electromagnet within a range of 0.5 mm to 2.1 mm.

### Clause 3

The plasma processing apparatus according to Clause 1 or 2, wherein a number of turns of the coil of the electromagnet within a range of 30 to 455.

### Clause 4

The plasma processing apparatus according to any one of Clauses 1 to 3, wherein
a current flowing through the coil of the electromagnet within a range of 1.3 A to 20 A.

### Clause 5

A plasma processing apparatus including:
a plasma processing chamber in which plasma processing space is formed;
a substrate support provided in the plasma processing chamber;
a gas introducer configured to introduce a gas into the plasma processing space;
an antenna provided above the plasma processing chamber and supplied with a source RF signal for forming plasma;
an AC power supply for supplying the source RF signal to the antenna;
an electromagnet provided radially outside the antenna and having an annular coil disposed concentrically with a central axis of the substrate support;
a DC power supply configured to supply power to the coil of the electromagnet; and
a controller, wherein
a number of turns of the coil of the electromagnet is within a range of 30 to 455.

### Clause 6

The plasma processing apparatus according to Clause 5, wherein
the wire diameter of the coil of the electromagnet is within a range of 0.5 mm to 2.1 mm.

### Clause 7

The plasma processing apparatus according to Clause 5 or 6, wherein
a current flowing through the coil of the electromagnet is within a range of 1.3 A to 20 A.

### Clause 8

A plasma processing apparatus including:
a plasma processing chamber in which plasma processing space is formed;
a substrate support provided in the plasma processing chamber;
a gas introducer configured to introduce a gas into the plasma processing space;
an antenna provided above the plasma processing chamber and supplied with a source RF signal for forming plasma;
an AC power supply for supplying the source RF signal to the antenna;
an electromagnet provided radially outside the antenna and having an annular coil disposed concentrically with a central axis of the substrate support;
a DC power supply configured to supply power to the coil of the electromagnet; and
a controller, wherein
the controller is configured to control the DC power supply in such a manner that a static magnetic field strength immediately below a top plate of the plasma processing chamber is within a range of 13 G to 22 G.

### Clause 9

The plasma processing apparatus according to any one of Clauses 1 to 8, wherein
an inner diameter of the coil of the electromagnet is equal to or greater than 540 mm and equal to or less than 640 mm.

### Clause 10

The plasma processing apparatus according to any one of Clauses 1 to 8, wherein
a pressure in the plasma processing chamber is equal to or greater than 3 mTorr and equal to or less than 10 mTorr.

### Clause 11

The plasma processing apparatus according to any one of Clauses 1 to 8, wherein
the controller is configured to
control the DC power supply to supply power to the coil of the electromagnet; and
control the AC power supply to supply the source RF signal to the antenna after the power is supplied to the coil of the electromagnet.

The present disclosure is not limited to the configuration described in the above embodiment or to combination with other elements and the like. These points can be altered within the scope of the present disclosure and can be appropriately defined in accordance with the application mode.

What is claimed is:

1. A plasma processing apparatus comprising:
a plasma processing chamber in which a plasma processing space is formed;
a substrate support provided in the plasma processing chamber;
a gas introducer having a gas introducing opening introducing a gas into the plasma processing space;
an antenna provided above the plasma processing chamber and supplied with a source RF signal for forming plasma;
an AC power supply for supplying the source RF signal to the antenna;
an electromagnet provided radially outside the antenna and having a coil disposed concentrically with a central axis of the substrate support, the coil being annular;
a DC power supply configured to supply power to the coil of the electromagnet; and
controller circuitry configured to control a current supplied by the DC power supply to the coil of the electromagnet such that a product of a number of turns of the coil and the current is within a range of 356 ampere-turns to 600 ampere-turns.

2. The plasma processing apparatus according to claim 1, wherein
a wire diameter of the coil of the electromagnet is within a range of 0.5 mm to 2.1 mm.

3. The plasma processing apparatus according to claim 1, wherein
a number of turns of the coil of the electromagnet is within a range of 30 to 455.

4. The plasma processing apparatus according to claim 1, wherein
a current flowing through the coil of the electromagnet is within a range of 1.3 A to 20 A.

5. The plasma processing apparatus according to claim 1, wherein
an inner diameter of the coil of the electromagnet is equal to or greater than 540 mm and equal to or less than 640 mm.

6. The plasma processing apparatus according to claim 1, further comprising an exhaust system,
wherein the controller circuitry is configured to control the exhaust system to maintain a pressure in the plasma processing chamber equal to or greater than 3 mTorr and equal to or less than 10 mTorr.

7. The plasma processing apparatus according to claim 6, wherein
the exhaust system is connected to a gas exhaust opening of the plasma processing chamber, and
the exhaust system comprises a pressure regulating valve and a vacuum pump.

8. The plasma processing apparatus according to claim 7, wherein the vacuum pump comprises at least one of a turbomolecular pump or a dry pump.

9. The plasma processing apparatus according to claim 1, wherein
the controller circuitry is further configured to:
control the DC power supply to supply power to the coil of the electromagnet; and
control the AC power supply to supply the source RF signal to the antenna after the power is supplied to the coil of the electromagnet.

10. The plasma processing apparatus according to claim 1, wherein
the controller circuitry is configured to control the AC power supply to supply a frequency of the source RF signal within a range of 10 MHz to 150 MHz.

11. The plasma processing apparatus according to claim 1, wherein:
the substrate support includes at least one bias electrode; and
the AC power supply comprises a first RF generator coupled to the antenna and configured to generate the source RF signal, and a second RF generator coupled to the at least one bias electrode and configured to generate a bias RF signal.

12. The plasma processing apparatus according to claim 11, wherein the controller circuitry is configured to control the AC power supply such that the bias RF signal has a frequency that is lower than a frequency of the source RF signal and the frequency of the bias RF signal is within a range of 100 kHz to 60 MHz.

13. The plasma processing apparatus according to claim 1, wherein the DC power supply is configured to supply pulsed power to the coil of the electromagnet.

14. A plasma processing apparatus comprising:
a plasma processing chamber in which a plasma processing space is formed;
a substrate support provided in the plasma processing chamber;
a gas introducer having a gas introducing opening introducing a gas into the plasma processing space;
an antenna provided above the plasma processing chamber and supplied with a source RF signal for forming plasma;
an AC power supply for supplying the source RF signal to the antenna;
an electromagnet provided radially outside the antenna and having a coil disposed concentrically with a central axis of the substrate support, the coil being annular;
a DC power supply configured to supply power to the coil of the electromagnet; and
controller circuitry configured to control the DC power supply to drive the coil, wherein
a number of turns of the coil of the electromagnet is within a range of 30 to 455.

15. The plasma processing apparatus according to claim 14, wherein
a wire diameter of the coil of the electromagnet is within a range of 0.5 mm to 2.1 mm.

16. The plasma processing apparatus according to claim 14, wherein
a current flowing through the coil of the electromagnet is within a range of 1.3 A to 20 A.

17. The plasma processing apparatus according to claim 14, wherein an inner diameter of the coil of the electromagnet is equal to or greater than 540 mm and equal to or less than 640 mm.

18. A plasma processing apparatus comprising:
a plasma processing chamber in which a plasma processing space is formed, the plasma processing chamber including a top plate;
a substrate support provided in the plasma processing chamber;
a gas introducer having a gas introducing opening introducing a gas into the plasma processing space;
an antenna provided above the plasma processing chamber and supplied with a source RF signal for forming plasma;
an AC power supply for supplying the source RF signal to the antenna;
an electromagnet provided radially outside the antenna and having a coil disposed concentrically with a central axis of the substrate support, the coil being annular;
a DC power supply configured to supply power to the coil of the electromagnet; and
controller circuitry configured to control the DC power supply to cause a static magnetic field strength immediately below the top plate of the plasma processing chamber is within a range of 13 G to 22 G.

19. The plasma processing apparatus according to claim 18, wherein
an inner diameter of the coil of the electromagnet is equal to or greater than 540 mm and equal to or less than 640 mm.

20. The plasma processing apparatus according to claim 18, wherein the controller circuitry is configured to control the DC power supply such that a current flowing through the coil of the electromagnet is within a range of 1.3 A to 20 A.
